(19) United States
(12) Patent Application Publication
(10) Pub. No.: US 2021/0159094 A1
(43) Pub. Date: May 27, 2021

(54) UNIVERSAL ADJUSTABLE BLOCKER PLATE FOR FLOW DISTRIBUTION TUNING

(71) Applicant: Applied Materials, Inc., Santa Clara, CA (US)

(72) Inventors: Yuxing ZHANG, Santa Clara, CA (US); Sanjeev BALUJA, Campbell, CA (US); Amit Kumar BANSAL, Milpitas, CA (US); Tuan Anh NGUYEN, San Jose, CA (US); Tejas ULAVI, San Jose, CA (US); Gopu KRISHNA, Whitefield, Bangalore (IN)

(21) Appl. No.: 17/046,916

(22) PCT Filed: Apr. 3, 2019
(86) PCT No.: PCT/US2019/025481

§ 371 Date: Oct. 12, 2020

(30) Foreign Application Priority Data
May 3, 2018 (IN) 201841016760

(51) Int. Cl. H01L 21/67; H01L 21/683; H01L 21/02

(52) U.S. Cl. CPC H01L 21/67017; H01L 21/67103; H01L 21/0228; H01L 21/6831

(57) ABSTRACT

A gas distribution apparatus is disclosed. The apparatus includes a faceplate and a blocker plate. An adjustment mechanism is coupled to the blocker plate and is operable to position the blocker plate relative to the faceplate in order to modify a flow profile of a gas flowing therethrough. A method of processing a substrate using the gas distribution is also disclosed.

### BACKGROUND

### Field

Embodiments of the present disclosure generally relate to a method and apparatus for distributing a gas in a processing chamber.

### Description of the Related Art

In the fabrication of integrated circuits, deposition processes such as chemical vapor deposition (CVD) or atomic layer deposition (ALD) are used to deposit films of various materials upon semiconductor substrates. In other operations, a layer altering process, such as etching, is used to expose a portion of a layer for further processing. Often, these processes are used in a repetitive fashion to fabricate various layers of an electronic device, such as a semiconductor device.

Conventional processing chambers utilize multiple designs of components to alter the flow of the gases to the substrate in order to achieve desired layer geometries thereon. However, having multiple designs of components often leads to downtime to replace one component with another component of a different design for a new process operation. Alternatively, multiple chambers are utilized with a different component design in each respective chamber. Such designs increase the cost of device manufacturing and lower the throughput of the processing systems.

Therefore, there is a need for improved components for processing substrates.

### SUMMARY

The present disclosure generally relates to a method and apparatus for distributing a gas in a processing chamber.

In one aspect, a gas distribution assembly is disclosed. The gas distribution assembly includes a faceplate and a blocker plate. An adjustment mechanism is coupled to the blocker plate. The adjustment mechanism is operable to set a distance between the faceplate and the blocker plate in order to modify a flow profile of a gas through the gas distribution assembly.

In another aspect, a processing chamber has a chamber body and a lid coupled thereto. A processing volume is defined within the chamber body and the lid wherein a substrate support is disclosed. A gas distribution assembly is coupled to the lid and includes a faceplate, a blocker plate, and an adjustment mechanism coupled to the blocker plate. The adjustment mechanism is operable to set a distance between the faceplate and the blocker plate.

In another aspect, a method for processing a substrate is disclosed. The method includes selecting a first processing gas; positioning a blocker plate relative to a faceplate in response to the selecting the first processing gas, wherein the position of the blocker plate achieves a desired flow distribution of the first processing gas; and flowing the first processing gas into a processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a cross-sectional view of a processing chamber, according to one embodiment.

FIG. 2 is a cross-sectional view of a processing chamber, according to another embodiment.

FIG. 3 is an enlarged cross-sectional view of a lid assembly, according to one embodiment.

FIG. 4 is a flow diagram of a method for processing a substrate, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to a gas distribution apparatus. The apparatus includes a faceplate and a blocker plate. An adjustment mechanism is coupled to the blocker plate and is operable to position the blocker plate relative to the faceplate in order to modify a flow profile of a gas flowing therethrough. A method of processing a substrate using the gas distribution is also disclosed.

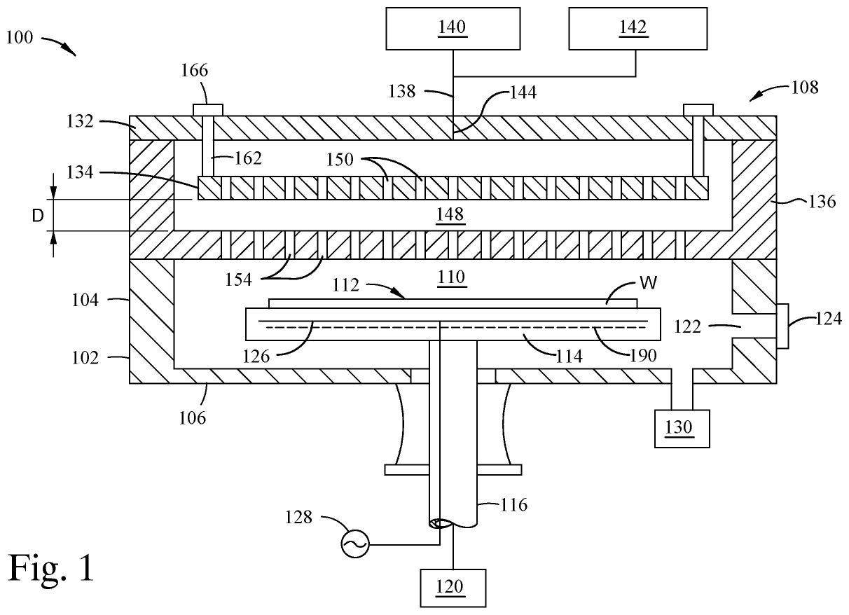

FIG. 1 is a schematic arrangement of an exemplary processing chamber 100 according to one embodiment. The processing chamber 100 has a body 102 having a sidewall 104 and base 106. A lid assembly 108 couples to the body 102 to define a processing volume 110 therein. The body 102 is generally formed from a metal, such as aluminum or stainless steel, but any material suitable for use with processing therein may be utilized. A substrate support 112 is disposed within the processing volume 110 and supports a substrate W during processing within the processing chamber 100. The substrate support 112 includes a support body 114 coupled to a shaft 116. The shaft 116 is coupled to a lower surface of the support body 114 and extends out of the body 102 through an opening 118 in the base 106. The shaft 116 is coupled to an actuator 120 to vertically move the shaft 116, and the support body 114 coupled thereto, between a substrate loading position and a processing position. A vacuum system 130 is fluidly coupled to the processing volume 110 in order to evacuate gases from the processing volume 110.

To facilitate processing of a substrate W in the processing chamber 100, the substrate W is disposed on the upper surface of the support body 114, opposite of the shaft 116. A port 122 is formed in the sidewall 104 to facilitate ingress and egress of the substrate W into the processing volume 110. A door 124, such as a slit valve, is actuated to selectively allow the substrate W to pass through the port 122 to be loaded onto, or removed from, the substrate support 112. An electrode 126 is optionally disposed within the support body 114 and electrically coupled to a power source 128 through the shaft 116. The electrode 126 is selectively biased by the power source 128 to create an electromagnetic field to chuck the substrate W to the upper surface of the support body 114 and/or to facilitate plasma generation or control. In certain embodiments, a heater 190, such as a resistive heater, is disposed within the support body 114 to heat the substrate W disposed thereon.

The lid assembly 108 includes a lid 132, a blocker plate 134, and a faceplate 136. The faceplate 136 is coupled to the lid 132 and together with the lid 132 defines a gas volume 148. The blocker plate 134 is disposed in the gas volume 148 and coupled to the lid 132 by adjustment mechanisms 162. In one embodiment, the adjustment mechanisms 162 include one or more actuators 166 disposed through the lid 132. In other embodiments, the adjustment mechanisms 162 are support blocks, screws, spacers, extensions, and the like that are coupled directly to the lid 132. A plurality of apertures 150 are optionally formed through the blocker plate 134. Here, the blocker plate 134, the faceplate 136, and the adjustment mechanisms 162 define a gas distribution assembly.

An inlet port 144 is disposed within the lid 132. The inlet port 144 is coupled to a gas conduit 138. The gas conduit 138 allows a gas to flow from a first gas source 140, such as a process gas source, through the inlet port 144 into the first gas volume 146. A second gas source 142, such as a cleaning gas source, is optionally coupled to the gas conduit 138. The first gas source 140 supplies a process gas, such as an etching gas or a deposition gas, to the processing volume 110 to etch or deposit a layer on the substrate W. The second gas source 142 supplies a cleaning gas to the processing volume 110 in order to remove particle depositions from internal surfaces of the processing chamber 100.

Apertures 154 are disposed through the faceplate 136. The apertures 154 allow fluid communication between the processing volume 110 and the gas volume 148. During operation, a gas is permitted to flow from the inlet port 144 into the gas volume 148 wherein the gas is distributed through the gas volume 148 by the blocker plate 134, and the apertures 150 in the blocker plate 134 when included. Then, the gas flows through the apertures 154 in the faceplate 136 into the processing volume 110. In order to modulate the distribution of the gas through the gas volume 148, the actuators 166 are operable to raise and lower the blocker plate 134 using the adjustment mechanisms 162 such that a distance D between the blocker plate 134 and the faceplate 136 increases or decreases. In embodiments that do not include the actuators 166, the adjustment mechanisms 162 can be adjusted, for example, by increasing or decreasing a length thereof, such as a nut/screw combination or replacement of the adjustment mechanisms 162 with a different adjustment mechanism 162 having a different length.

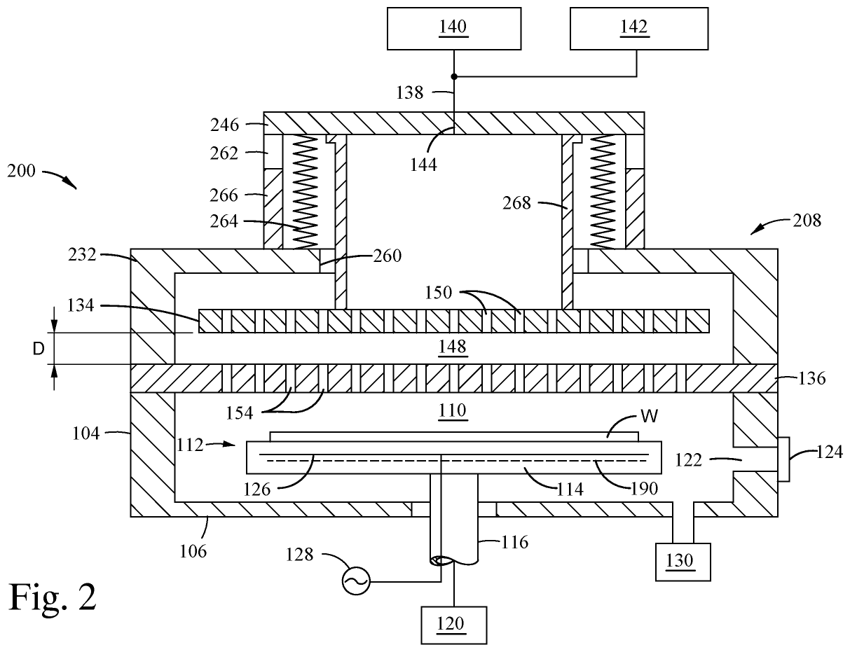

FIG. 2 is another embodiment of a processing chamber 200. The processing chamber 200 is similar to the processing chamber 100 but uses a different arrangement of a lid assembly 208. In the embodiment of FIG. 2, the lid assembly 208 again includes a faceplate 136, a lid 232, and a blocker plate 134 disposed therebetween in a gas volume 148. The lid 232 has a port 260 formed therethrough. A bellows 264 is disposed surrounding the port 260 coupled to the lid 232 at a first end and a cap 246 at a second end. The cap 246 and the bellows 264 partially define the gas volume 148. Here, an inlet port 144 is formed through the cap 246. Therefore, the gas volume 148 is in fluid communication with the gas sources 140, 142 through a gas conduit coupled to the inlet port 144.

The blocker plate 134 is coupled to the cap 246 by one or more extensions 268 which extend through the port 260 in the lid 232. The extensions 268 provide a rigid connection between the cap 246 and the blocker plate 134. In one embodiment, a single extension 268 having a cylindrical body with a gas flow path from the cap 246 to the blocker plate 134 defined therein is used. In other embodiments, multiple extensions 268 are used and are, for example, arranged in a polar array about a central axis of the blocker plate 134.

The cap 246 is coupled to the lid 232 by one or more adjustment mechanisms 262. The adjustment mechanisms 262 optionally include one or more actuators 266. In these cases, the actuators 266 are operable to raise and lower the cap 246 thereby changing a distance between the faceplate 136 and the blocker plate 134 which is coupled to the adjustment mechanisms 262 by the extensions 268 and the cap 246. In other embodiments, the adjustment mechanisms 262 may be screws, standoffs, blocks, spacers, or the like which may be fixed or movable in order to modulate the distance between the faceplate 136 and the blocker plate 134. For example, the adjustment mechanisms 262 may be blocks that may be replaced with blocks of different lengths to change the spacing between the blocker plate 134 and the faceplate 136. In another example, the adjustment mechanisms 262 are threaded jacks (i.e., a screw and nut member) which may be lengthened or shortened to raise and lower the cap 246. The bellows 264 maintains isolation of the gas volume 148 while allowing the adjustment mechanism 262 to move in order to position the blocker plate 134 as desired.

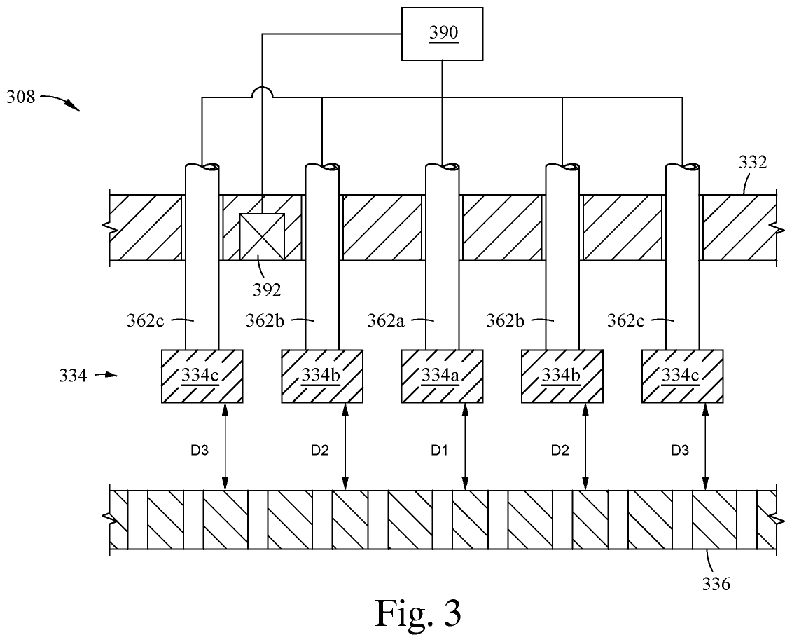

FIG. 3 is a schematic arrangement of an enlarged portion of an exemplary lid assembly 308 of another embodiment. FIG. 3 illustrates a lid 332 and a faceplate 336. A blocker plate 334 is disposed between the lid 332 and the faceplate 336. Here, the blocker plate 334 is formed from three members: a first member 334a, a second member 334b, and a third member 334c. In the embodiment of FIG. 3, the blocker plate member 334a is a disc shaped member and the blocker plate members 334b, 334c are concentric rings disposed about the blocker plate member 334a. That is, the blocker plate members 334a, 334b, 334c are concentrically arranged about a central axis of the blocker plate 334. It is to be understood that other shapes, such as square or ovoid, among others, and other numbers, such as one, two, four, five, or even more, of members used to form the blocker plate 334 may be used herewith.

Each blocker plate member 334a, 334b, 334c is coupled to a respective adjustment mechanism 362a, 362b, 362c. Here, the adjustment mechanisms 362a, 362b, 362c representatively extend through the lid 332 and couple to an actuator (not shown). However, other types and/or number of adjustment mechanisms 362 may be used herewith. In the embodiment of FIG. 3, each adjustment mechanism 362a, 362b, 362c are individually controllable to raise and lower the respective blocker plate member 334a, 334b, 334c. Therefore a distance between the blocker plate members 334a, 334b, 334c and the faceplate may be changed. For example, a first distance D₁ between the first blocker plate member 334a and the faceplate has a length set by the first adjustment mechanism 362a. A second distance D₂ between the second blocker plate member 334b and the faceplate 336 has a length set by the second adjustment mechanism 362b. A third distance D₃ between the third blocker plate member 334c and the faceplate 336 has a length set by the third adjustment mechanism 362c. Therefore, the distribution of the gas across the blocker plate 334 to the faceplate 336 can be controlled by setting each distance D₁, D₂, and D₃ to a desired length. Adjustment of each distance D₁, D₂, and D₃ results in a corresponding change in the gas flow distribution through the faceplate 336.

In another example, a controller 390 is optionally coupled to the adjustment mechanisms 362a, 362b, and 362c, such as, through actuators (not shown). The controller 390 is operable to raise and lower the adjustment mechanisms 362a, 362b, 362c, and the respective blocker plate members 334a, 334b, 334c to desired positions. For example, a control scheme may be stored in the controller 390 for processing a substrate using predefined values for the distances D₁, D₂, and D₃ to achieve a desired gas distribution across the substrate. A sensor 392 is also optionally disposed in the lid 332 and coupled to the controller 390. In one example, the sensor 392 is utilized to determine a gas distribution or flow of the gas from the blocker plate 334 to the faceplate 336. The sensor 392 provides a measured or determined parameter to the controller 390 which may adjust the processing system, including the distance between the blocker plate 334 and the faceplate and/or a flow from a gas source, to achieve a desired gas distribution.

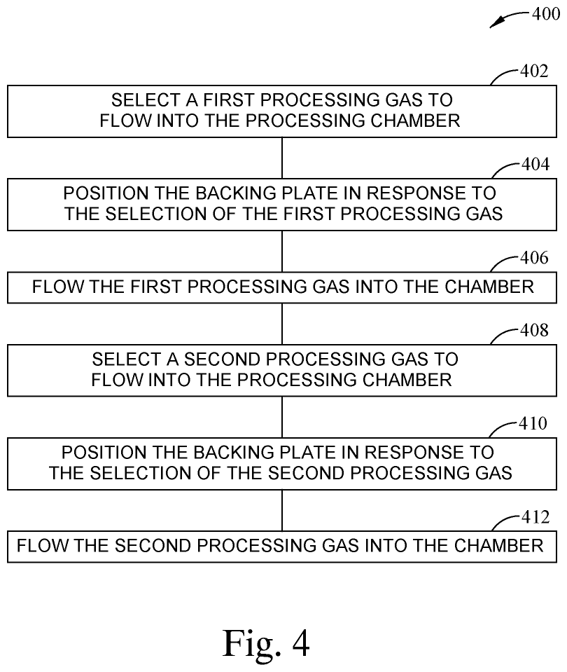

FIG. 4 is flow diagram of an exemplary method 400 for processing a substrate. The method may be utilized with the lid assemblies 108, 208, 308 described herein, though other assemblies may also be used. The method 400 begins by selecting a first processing gas to flow into a processing chamber at operation 402. For example, a first gas may be a precursor gas for depositing a layer on a substrate, an etching gas, or a cleaning gas, among others.

At operation 404, a position of the blocker plate (i.e., relative location of the blocker plate to the faceplate) is established in relation to the selected first processing gas. The blocker plate is positioned relative to the faceplate to achieve a desired distribution of the first processing gas across the substrate. The blocker plate may be a single body or formed form multiple members as described herein. The blocker plate may be positioned by an operator or automatically by a control system.

At operation 406, the first processing gas is flowed into a processing chamber having a substrate disposed therein. The position of the blocker plate is optionally adjusted during the flowing of the first processing gas in order to maintain a desired distribution of the first processing gas across the substrate. In one example, the positon of the blocker plate is adjusted by a controller in response to a measure parameter by a sensor.

At operation 408, a second processing gas is selected. The second processing gas may be, for example, a precursor gas for a deposition process, an etching gas, or a cleaning gas, among others.

At operation 410, a second positon of the blocker plate is determined in response to the selection of the second processing gas. The blocker plate is positioned relative to the faceplate again to achieve a desired distribution of the second processing gas across the substrate. In one example, the second positon of the blocker plate is different than the first position established at operation 404. However, the first position and the second position may be the same.

At operation 412, the second processing gas is flowed into the processing chamber. The position of the blocker plate is again optionally adjusted during the flowing of the first processing gas in order to maintain a desired distribution of the first processing has across the substrate as described above.

The embodiments described herein advantageously provide tunable flow of a gas through a gas distribution apparatus. In one aspect, a single distribution apparatus can be utilized for multiple process steps which increases throughput of the processing chamber used therewith since downtime of the processing chamber to replace a component with another component of a different design is not required. Further, the properties of the film formed on the substrate are improved by providing better control of the flow of the gas to the substrate. For example, zones can be established corresponding to the desired flow(s) of a process gas thereto. The embodiments herein provide increased control of the gas distribution to the respective zones. Still further, the center-to-edge radial flow profile can be controlled to provide various shapes thereof.

While the foregoing is directed to embodiments of the present disclosure, other and further embodiments of the disclosure may be devised without departing from the basic scope thereof, and the scope thereof is determined by the claims that follow.

1. A gas distribution assembly comprising:
a faceplate;
a blocker plate; and
an adjustment mechanism coupled to the blocker plate and operable to set a distance between the faceplate and the blocker plate.

2. The gas distribution assembly of claim 1, wherein the blocker plate comprises a plurality of members.

3. The gas distribution assembly of claim 2, wherein the plurality of members comprises concentrically arranged bodies about a central axis of the blocker plate.

4. The gas distribution assembly of claim 2, wherein a distance between each member of the plurality of members is individually adjustable relative to the other members.

5. The gas distribution assembly of claim 1, wherein the adjustment mechanism comprises an actuator.

6. The gas distribution assembly of claim 1, wherein the adjustment mechanism comprises spacers.

7. The gas distribution assembly of claim 1, further comprising a sensor disposed adjacent to the blocker plate.

8. The gas distribution assembly of claim 1, further comprising an extension coupled to the blocker plate and the adjustment mechanism, wherein a gas flow path is defined within the extension.

9. A processing chamber comprising:
a chamber body;
a lid coupled to the chamber body, wherein a processing volume is defined within the chamber body and the lid;
a substrate support disposed within the processing volume; and
a gas distribution assembly coupled to the lid, the gas distribution assembly comprising:
a faceplate;
a blocker plate; and
an adjustment mechanism coupled to the blocker plate and operable to set a distance between the faceplate and the blocker plate.

10. The processing chamber of claim 9, wherein the blocker plate comprises a plurality of members.

11. The processing chamber of claim 10, wherein the plurality of members comprise concentrically arranged bodies about a central axis of the blocker plate.

12. The processing chamber of claim 10, wherein a distance between each member of the plurality of members is individually adjustable relative to the other members.

13. A method for processing a substrate comprising:
selecting a first processing gas;
positioning a blocker plate relative to a faceplate in response to the selecting the first processing gas, wherein the position of the blocker plate achieves a desired flow distribution of the first processing gas; and
flowing the first processing gas into a processing chamber.

14. The method of claim 13, further comprising:
selecting a second processing gas;
positioning the blocker plate relative to the faceplate in response to the selecting the second processing gas, wherein the position of the blocker plate achieves a desired flow distribution of the second processing gas; and
flowing the second processing gas into the processing chamber.

15. The method of claim 13, wherein a controller and an actuator are configured to position the blocker plate relative to the faceplate.

16. The gas distribution assembly of claim 1, wherein the blocker plate comprises a single member.

17. The processing chamber of claim 9, wherein the adjustment mechanism comprises an actuator.

18. The processing chamber of claim 9, wherein the adjustment mechanism comprises spacers.

19. The processing chamber of claim 9, further comprising a sensor disposed within the lid.

20. The method of claim 13, wherein flowing the first processing gas into a processing chamber comprises further adjusting the position of the blocker plate relative to the faceplate while flowing the first processing gas to maintain the desired flow distribution.
